(19) United States
(12) Patent Application Publication
(10) Pub. No.: US 2009/0209065 A1
(43) Pub. Date: Aug. 20, 2009

(54) METHOD OF MANUFACTURING SEMICONDUCTOR DEVICE AND ULTRASONIC BONDING APPARATUS

(76) Inventors: Hideo NISHIUCHI, Yokohama-shi (JP); Tomohiro Iguchi, Kawasaki-shi (JP); Tomoyuki Kitani, Fujisawa-shi (JP); Takahiro Aizawa, Yokohama-shi (JP); Masako Fukumitsu, Yokohama-shi (JP); Akira Tojo, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/367,637

(22) Filed: Feb. 9, 2009

(30) Foreign Application Priority Data
Feb. 14, 2008 (JP) 2008-033316

(51) Int. Cl. H01L 21/78; B23K 1/06

(52) U.S. Cl. 438/113; 228/110.1; 228/1.1; 257/E21.599

(57) ABSTRACT

An example of the invention is a method of manufacturing a semiconductor device including, pressing a part of the connection conductor having a plate-like shape or a belt-like shape against a lead terminal which is formed on a lead frame, is formed into a thin and long plate-like shape, and is supported only at one end in a longitudinal direction of the terminal, in such a manner that the part of the conductor is brought into contact with the lead terminal, and applying ultrasonic vibration substantially in the longitudinal direction in a plane perpendicular to the pressing direction to the connection conductor in the state where the part of the connection conductor is pressed against the lead terminal.

### CROSS-REFERENCE TO RELATED APPLICATIONS

This application is based upon and claims the benefit of priority from prior Japanese Patent Application No. 2008-033316, filed Feb. 14, 2008, the entire contents of which are incorporated herein by reference.

### BACKGROUND OF THE INVENTION

1. Field of the Invention

The present invention relates to a method of manufacturing a semiconductor device and an ultrasonic bonding apparatus, and more particularly, to a method and apparatus used when a plate- or belt-like connection conductor is bonded to an electrode of a semiconductor chip and a lead terminal of a lead frame astride them.

2. Description of the Related Art

In connection with a semiconductor device applied to a power source section (used for a DC-DC converter or a medium-current switch) of a cellular phone, digital camera, video camera, portable audio, IC recorder and the like, in order to make the resistance value of a package small, a structure in which an upper surface electrode of a semiconductor chip and a lead terminal are connected to each other by a connection conductor which is a metallic plate having a larger cross section than a wire, and is formed into a plate- or belt-like shape, is used. The connection conductor is arranged astride an upper surface electrode of a semiconductor chip mounted on a lead frame, and a lead terminal formed in the lead frame, and is connected to the upper surface electrode and the lead terminal by ultrasonic bonding.

As an ultrasonic bonding apparatus used for ultrasonic bonding, as shown in, for example, Jpn. Pat. Appln. KOKAI Publication No. 2004-221294, an ultrasonic bonding apparatus including a first pressing section for pressing a bonding section of an upper surface electrode of a semiconductor chip, and a connection conductor, a second pressing section for pressing a bonding section of a lead terminal of a lead frame, and the connection conductor, and a plurality of protrusions formed on the first and second pressing sections, is used. In a state where the connection conductor is pressed against the upper surface electrode and the lead terminal from above by using the tool section by means of the first and second pressing sections in such a manner that the connection conductor is brought into pressure contact with the upper surface electrode and the lead terminal, the connection conductor is subjected to minute mechanical vibration (ultrasonic vibration) at an ultrasonic frequency, whereby solid-state welding is achieved by the friction at the interface between the connection conductor and each of the upper surface electrode and the lead terminal.

However, in the technique described above, there has been the following problem. That is, when the connection conductor is subjected to ultrasonic vibration in the state where the connection conductor is pressed against the lead terminal from above, the lead terminal is vibrated together with the connection conductor as one body in some cases. In this case, the relative motion is hindered, and the solid-state welding to be achieved by the friction at the interface is disturbed. As a result of this, the connection conductor and the lead terminal are not connected satisfactorily to each other, thereby causing deterioration of the performance of the semiconductor device.

### BRIEF SUMMARY OF THE INVENTION

An aspect of the invention is a method of manufacturing a semiconductor device comprising, pressing a part of the connection conductor having a plate-like shape or a belt-like shape against a lead terminal which is formed on a lead frame, is formed into a thin and long plate-like shape, and is supported only at one end in a longitudinal direction of the terminal, in such a manner that the part of the conductor is brought into contact with the lead terminal, and applying ultrasonic vibration substantially in the longitudinal direction in a plane perpendicular to the pressing direction to the connection conductor in the state where the part of the connection conductor is pressed against the lead terminal.

An another aspect of the invention is an ultrasonic bonding apparatus comprising, a stage on which a lead frame including lead terminals each having a thin and long shape and semiconductor chips mounted thereon is to be placed, and a tool section for pressing, in a state where a connection conductor having a plate-like shape or a belt-like shape is arranged astride an electrode formed on an upper surface of the semiconductor chip and the lead terminal, a part of the connection conductor against the lead terminal in such a manner that the part of the conductor is brought into contact with the lead terminal, and applying ultrasonic vibration substantially in the longitudinal direction in a plane perpendicular to the pressing direction to the connection conductor in the state where the part of the connection conductor is pressed against the lead terminal.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view showing a semiconductor device according to an embodiment of the present invention;

FIG. 2 is a plan view showing a lead frame according to the embodiment;

FIG. 3 is a perspective view showing an ultrasonic bonding apparatus according to the embodiment;

FIG. 4 is a bottom view showing a tool section of the ultrasonic bonding apparatus;

FIG. 5 is a side view showing a method of manufacturing the semiconductor device according to the embodiment of the present invention;

FIG. 6 is a side view showing the method of manufacturing the semiconductor device;

FIG. 7 is a side view showing the method of manufacturing the semiconductor device;

FIG. 8 is a plan view showing the method of manufacturing the semiconductor device;

FIG. 9 is a side view showing the method of manufacturing the semiconductor device;

FIG. 10 is a view for explaining the method of manufacturing the semiconductor device;

FIG. 11 is a graph showing the amplitude at the time of bonding by the method of manufacturing the semiconductor device and that at the time of bonding by another method in comparison with each other; and

FIG. 12 is a graph showing the bonded state by the method of manufacturing the semiconductor device and that by another method in comparison with each other.

### DETAILED DESCRIPTION OF THE INVENTION

A semiconductor device 1 and an ultrasonic bonding apparatus 30 according to an embodiment of the present invention will be described below with reference to the accompanying drawings. It should be noted that in each drawing, the configuration shown is appropriately enlarged, reduced, or omitted. In the drawings, arrows X, Y, and Z indicate three directions perpendicular to each other.

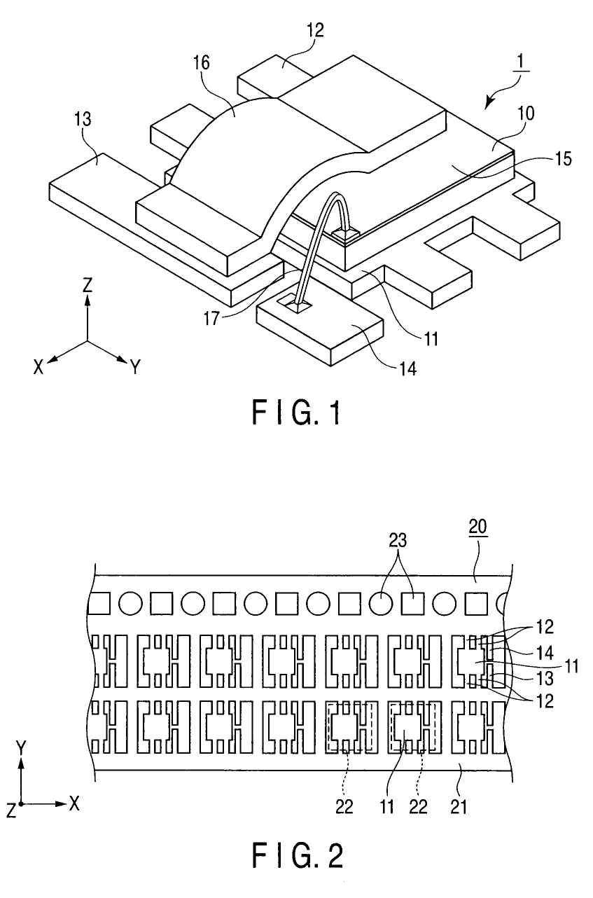

FIG. 1 is a perspective view of a semiconductor device 1 according to the embodiment. FIG. 2 is a plan view of a lead frame 20. The semiconductor device 1 of this embodiment is a small-signal transistor or a small-signal semiconductor device which is formed in a size of several mm square, is small in size and thickness, has features of a low Rₒₙ, low capacity, low power consumption, low voltage drive, and the like, and is applied to a power source section (used for a DC-DC converter or a medium-current switch) of a cellular phone, digital camera, video camera, portable audio, IC recorder, and the like.

The semiconductor device 1 shown in FIG. 1 includes a semiconductor chip 10, an island section 11 on which the semiconductor chip 10 is mounted, a terminal 12 integrally extending from the island section 11, and functioning as, for example, a drain electrode, a lead terminal 13 independently arranged in the vicinity of the island section, and functioning as, for example, a source electrode, and a terminal 14 independently arranged in the vicinity of the island section, and functioning as, for example, a gate electrode. The semiconductor device 1 functions as a switch in which when a predetermined voltage is applied to the terminal 14 functioning as the gate, a predetermined current flows from the lead terminal 13 functioning as the source to the terminal 12 functioning as the drain. The semiconductor device 1 is configured in such a manner that the size thereof is, for example, several mm square, and the width of the terminals 12 to 14 thereof, or the interval between the terminals is, for example, about several hundred μm.

An upper surface electrode 15 formed on the semiconductor chip 10, and the lead terminal 13 are connected to each other through a connection conductor 16 serving as a connection conductor arranged astride the electrode 15 and the lead terminal 13, and the upper surface electrode 15 and the terminal 14 are connected to each other by a metallic wire 17.

FIG. 2 shows a lead frame 20 of this embodiment. In the lead frame 20, a plate-like member made of metal such as copper or the like is formed into a predetermined belt-like shape. The lead frame 20 corresponds to a plurality of semiconductor devices 1. In the lead frame 20, a plurality of units (seven units in FIG. 2) each constituted of a square island section 11, and terminals 12 to 14 each having a thin and long shape, and extending in a first direction indicated by the arrow Y, are juxtaposed in a transfer direction indicated by the arrow X in FIG. 2. At the same time, two units each including the island section 11, and the terminal 12 to 14 are arranged in the first direction.

The plurality of island sections 11 and terminals 12 to 14 are formed together with a frame section 21 having a frame-like shape as one body. At an outer edge of the frame section 21, i.e., at an edge of the end part in the first direction, a plurality of engagement holes 23 for positioning at the time of transfer are formed in the second direction. Positioning pins (not shown) formed to be juxtaposed at a predetermined position of a stage block (stage) 31 are inserted in the engagement holes 23 to be engaged with the holes 23, whereby the lead frame 20 is transferred in the second direction by a transfer means (not shown). As a result of this, a plurality of lead frame units 22 juxtaposed in the second direction are passed through various processing apparatuses in sequence from the one end side to the other end side, and the lead frame units 22 are subjected in sequence to various types of processing. A part in FIG. 2 encircled by a broken line is a lead frame unit 22 corresponding to one semiconductor device 1. A plurality of semiconductor devices 1 are collectively manufactured, are molded with a resin 40, and thereafter the devices 1 are divided into separate lead frame units 22. It should be noted that although FIG. 1 shows the semiconductor device 1 after the division, the molding resin 40 is omitted in the figure. It should be noted that a cross-sectional view of the molded state is shown in FIG. 10.

Each of the plurality of island sections 11 is formed into a square plate-like shape. The terminals 12 are formed integral with the island section 11 to extend from the four corners of the island section 11, i.e., from the right, left, front, and rear part of the section 11 in the first direction, and are connected to the frame section 21. The lead terminal 13, and the terminal 14 which are each formed into a thin and long rectangular plate-like shape, and each extend in the Y direction as the longitudinal direction are formed at positions adjacent to the island section 11 in the second direction. An upper surface of the lead terminal 13 becomes the bonding interface to be subjected to ultrasonic bonding. The lead terminal 13 and the terminal 14 are each supported by the frame section 21 only at their proximal end parts which are their outside end parts to be formed integral with the frame section 21. The distal end part on the other end side of each of the lead terminal 13 and the terminal 14 is free.

That is, the lead terminal 13 has a thin and long plate-like shape supported at one end thereof, and hence the rigidity thereof in the first direction is higher than that in the second direction in the horizontal plane formed by the second direction along the arrow X and the first direction along the arrow Y. That is, in the lead terminal 13, the end part thereof in the first direction, which is parallel with the longitudinal direction thereof, i.e., in the longitudinal direction is formed integral with the lead frame 20 to be fixed, and hence the lead terminal 13 is hardly vibrated in the first direction. However, in the second direction (X direction) which is the width direction, the end part thereof is not fixed, and moreover the lead terminal 13 has a thin and long shape, and hence the lead terminal 13 is liable to be vibrated by the force in the second direction, i.e., in the width direction.

The semiconductor chip 10 is mounted on the island section 11 of the lead frame 20. On the upper surface of the semiconductor chip 10, the upper surface electrode 15 constituted of an aluminum material is formed. An upper surface of the upper surface electrode 15 becomes the bonding interface to be subjected to ultrasonic bonding, and is connected to the lead terminal 13 through the connection conductor 16. It should be noted that the aluminum material mentioned in this description implies a material constituted of aluminum or an aluminum alloy.

The connection conductor 16 is a member made of, for example, an aluminum material, and having a plate- or belt-like shape, and is arranged astride the upper surface electrode 15 and the lead terminal 13. A central part of the connection conductor 16 is formed into a curved shape, and the undersurfaces of both end parts constitute the bonding interfaces to be bonded to the upper surface electrode 15, and the lead terminal 13.

The connection conductor 16 constitutes a tunnel part which is extended in the second direction, a central part of which is curved in the upward direction.

The connection conductor 16 is upwardly separated from the semiconductor chip 10 at the tunnel part 16a. Thus, the connection conductor 16 provides a gap that can be passed through in the first direction, between itself and the semiconductor chip 10 and the upper surface electrode 15.

An undersurface (a part thereof) on one end side of the connection conductor is connected to the lead terminal 13, and an undersurface (the other part) on the other end side of the connection conductor is connected to the upper surface electrode 15 of the semiconductor chip 10. The upper surface electrode 15 is positioned higher than the lead terminal 13, and hence the connection conductor 16 is configured in such a manner that the undersurface on the other end side is positioned higher than that on the one end side. The undersurfaces of both the ends of the connection conductor 16 become the bonding interfaces to be subjected to ultrasonic bonding.

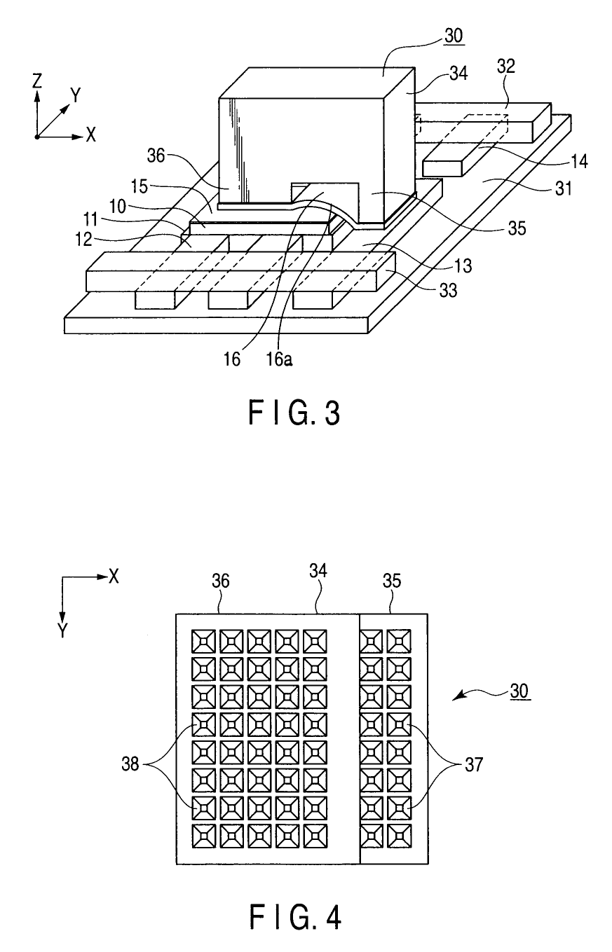

An ultrasonic bonding apparatus 30 for bonding the connection conductor 16 to the upper surface electrode 15 and the lead terminal 13 will be described below with reference to FIGS. 3 and 4. FIG. 3 is a perspective view of the ultrasonic bonding apparatus 30 on which a semiconductor device is set, and FIG. 4 is a bottom view of a tool section 34.

The ultrasonic bonding apparatus 30 achieves solid-state welding by subjecting the bonding interface to friction by applying pressure and strong ultrasonic vibration to the connection conductor. The ultrasonic bonding apparatus 30 includes a stage block 31 on which the lead frame 20 is placed, fixing jigs 32 and 33 for fixing the lead frame 20 to the stage block 31, and a tool section 34 positioned above the stage block 31, and is attached to a distal end of an ultrasonic horn (not shown).

The tool section 34 is movable in, for example, the up-and-down direction along the arrow Z in FIG. 3 and the first direction, and can subject the semiconductor devices 1 which are the objects of processing, and are arranged in two rows in the first direction in sequence to the processing.

The undersurface of the tool section 34 includes, as shown in FIG. 4, a first pressing section 35 for downwardly pressing a bonding part of the one end side of the connection conductor 16 and the lead terminal 13, and a second pressing section 36 for downwardly pressing a bonding part of the other end side of the connection conductor 16 and the upper surface electrode 15. Further, a step corresponding to a distance between the level of the upper surface electrode 15 of the semiconductor chip 10, and the level of the lead terminal 13, i.e., a difference between the height of the upper surface electrode 15 and the height of the lead terminal 13, is formed between the first pressing section 35 and the second pressing section 36. Furthermore, a plurality of protrusions 37, 38 each formed into a shape of a trapezoid of a quadrangular pyramid, and having the same size are formed on the first pressing section 35, and the second pressing section 36, respectively, in a lattice-like form. The protrusions 37, 38 are formed in rows in the first and second directions with about 0.3 mm pitches, and more protrusions 38 are provided on the second pressing section 36 having a larger area. The bonding surface can be uniformly pressed by the protrusions 37, 38.

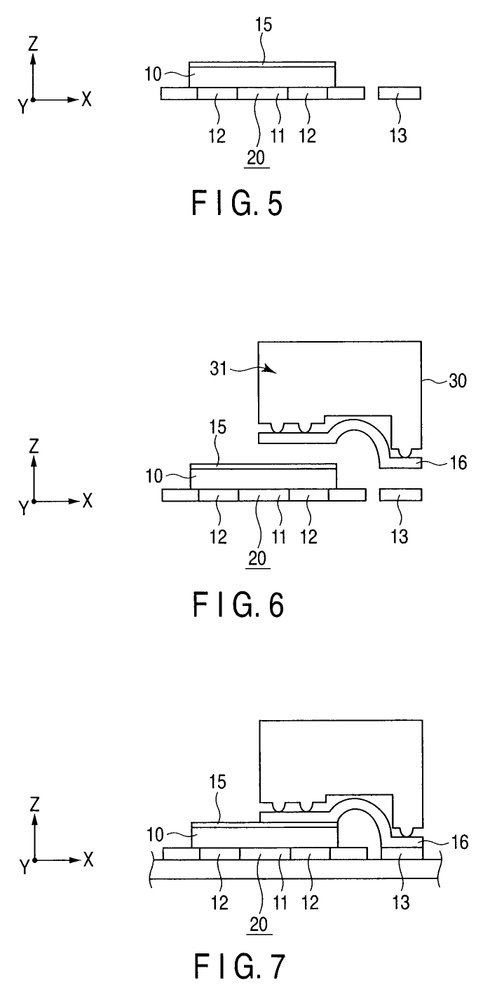

Next, a method of manufacturing the semiconductor device 1 according to this embodiment will be described below with reference to FIGS. 5 to 10. First, the lead frame 20, connection conductor 16, and semiconductor chip 10 are prepared, and the connection conductor is set at the storage section of the ultrasonic bonding apparatus 30.

Then, as shown in FIG. 5, the semiconductor chip 10 is fixed to the island section 11 through, for example, high-temperature solder. As the type of the high-temperature solder, for example, Pb-rich solder, AuGe solder, AuSn solder, or the like is used.

Then, as shown in FIG. 6, the lead frame 20 is transferred to the stage block 31, the connection conductor 16 is placed on the lead frame 20 and the semiconductor chip 10, and further, the one end part of the connection conductor 16 is placed on top of the lead terminal 13, and the other end part of the connection conductor 16 is placed on top of the upper surface electrode 15 by the tool section 34.

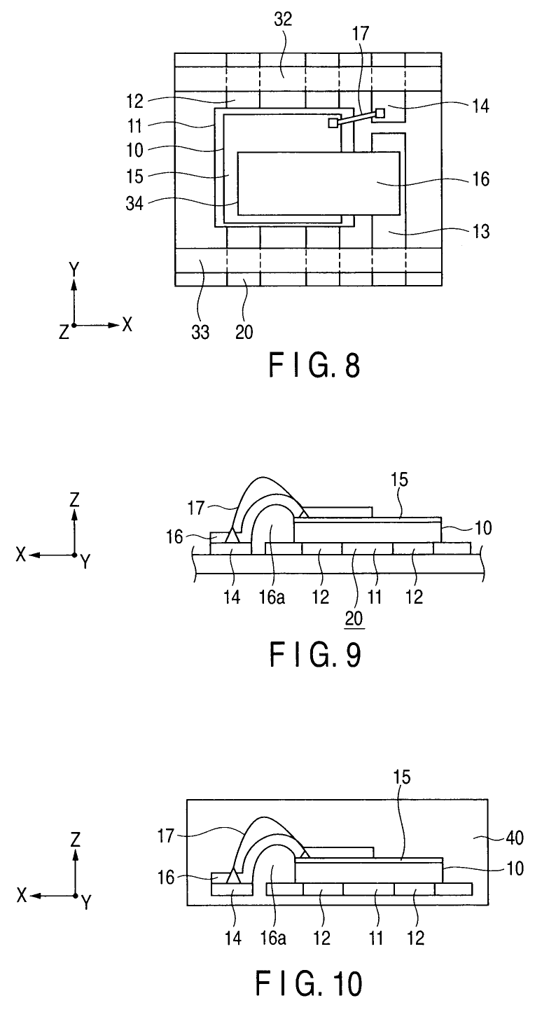

Subsequently, the bonding process is carried out by using the tool section 34. That is, as shown in FIGS. 7 and 8, in a state where the terminals 12 to 14 of the lead frame 20 are fixed by the fixing jigs 32 and 33 extending in the second direction, the tool section 34 is lowered in the Z direction, the one end part of the connection conductor 16, and the lead terminal 13 are downwardly pressed by the first pressing section 35 of the tool section, simultaneously, the other end part of the connection conductor 16, and the upper surface electrode 15 are pressed downwardly by the second pressing section 36, and, at the same time, ultrasonic vibration is applied in the horizontal direction, and in the first direction in which the rigidity of the lead terminal 13 is high, i.e., in the Y direction, whereby the connection conductor 16 is bonded to the lead terminal 13 and the upper surface electrode 15.

In this way, the lead terminal 13, and the upper surface electrode 15 are simultaneously bonded, by the ultrasonic bonding, to the one end part of the connection conductor 16, and the other end part thereof, respectively, and the connection conductor 16 is bonded to the lead terminal 13 of the lead frame 20, and the upper surface electrode 15 with sufficient strength.

It should be noted that when the direction of the vibration is determined, the lead frame 20 is vibrated at, for example, the frequency of the ultrasonic vibration, a relationship between the vibration direction and the amplitude of the lead terminal 13 of the lead frame 20 is acquired, a relationship between the vibration direction and the rigidity of the lead terminal 13 of the lead frame 20 is thus acquired, whereby the vibration direction in which the rigidity is low is determined. In this determination, use of numerical analysis such as the finite element method, and the like is also conceivable. Ultrasonic vibration is applied in a direction different from the vibration direction in which the rigidity is low. The vibration direction may be set in advance by the ultrasonic bonding apparatus 30, or a function of calculating and determining the above vibration direction in accordance with the lead frame 20 may be provided as a function of the ultrasonic bonding apparatus 30.

The bonding mechanism of the ultrasonic bonding will be described below. In the ultrasonic bonding, one of two metallic members of the same type or different types is put on top of the other, and, in this state, the two metallic members are placed on the stage block 31 and, in the state where a vertical load is applied to the bonding surface, ultrasonic vibration parallel with the bonding surface is applied to the bonding surface, whereby the two metallic members are bonded to each other in an extremely short time.

On the metal surfaces, which are the objects of the bonding, i.e., on the undersurfaces of both the ends of the connection conductor 16, the upper surface electrode 15, and the upper surface of the lead terminal 13, there are absorbed substances or oxide films, and the metal surfaces are not smooth from a microscopic point of view. In the ultrasonic bonding, first, by applying ultrasonic vibration, the two metallic members, which are the objects of the bonding, are subjected to relative friction caused between the two metallic members. By this friction, the absorbed substances or oxide films on the objective metal surfaces are broken, the contact surfaces are mechanically cleaned, and smoothed, and adhesion occurs between the metallic members. Then, relative motion takes place between each of the upper surface electrode 15 and the upper surface of the lead terminal 13, and the connection conductor 16, which is the object of the bonding, and the bonding area is enlarged by the sudden plastic flow.

As described above, in the ultrasonic bonding, it is a necessary condition that the oxide films on the bonding surfaces be removed by the relative motion of the two metallic members, and it is important to positively contrive to satisfy the condition from the standpoint of satisfactory execution of the ultrasonic bonding. In this embodiment, in the state where one end side of each of the terminals 12 to 14 is supported together with the frame section 21 as one body, and is fixed to and supported by the fixing jigs 32 and 33, the ultrasonic vibration is applied in the first direction in which the rigidity of the lead terminal 13 is high, and thus the lead terminal 13 is restrained from being moved together with the connection conductor 16, and the relative motion of the metallic members is enhanced, whereby the friction between both the members is promoted. As a result of this, the connection conductor 16 and the lead terminal 13 are strongly bonded to each other by the above bonding process.

After the bonding process, further, the terminal 14, which will become the gate electrode, is connected to the semiconductor chip by a metallic wire 17 as shown in FIG. 9.

Thereafter, the lead frame 20 is transferred in the second direction to a molding apparatus, and is molded by using a resin 40. In this resin molding process, filling processing of the resin 40 is performed by the resin molding die in the first direction perpendicular to the second direction in which the lead frame 20 is transferred. As a result of this, it is possible to satisfactorily fill the inside of the curved tunnel part 16a of the connection conductor 16 with the resin 40. That is, the lead terminal 13 and the upper surface electrode 15 are arranged side by side in the second direction, and hence the tunnel part 16a of the connection conductor 16 connecting the terminal 13 and the electrode 15 to each other, extends in the first direction. Accordingly, by performing the processing in the direction perpendicular to the transfer direction, it is possible to satisfactorily fill even the inside of the tunnel part 16a with the resin 40. Accordingly, the apparatus operating in the direction perpendicular to the transfer direction can be arranged in the transfer direction, and hence the installation is facilitated.

After this, through various types of processing such as honing, marking, plating, separation, testing, taping, and the like, the semiconductor device 1 is completed. It should be noted that the side views of FIGS. 9 and 10 are the side views of FIGS. 5 to 8 viewed from the opposite side.

In this embodiment, the lead frame 20, in which a number of island sections 11 and the terminals 12 to 14 are arranged in the second direction, is positioned by the engagement holes 23, transferred in the second direction, and while the parts which are the processing objects of the tools for various types of processing such as ultrasonic bonding, resin molding, and the like, are passed in sequence in the second direction, they are subjected to the various types of processing in sequence, whereby a number of semiconductor devices 1 are collectively manufactured.

At this time, the transfer means (not shown) is engaged with the engagement holes 23, the lead frame 20 is transferred in the second direction, i.e., in the X direction, while the lead frame 20 is moved, and a plurality of lead frame units 22 are repeatedly subjected to the above processing in sequence by the tool section 34, whereby a number of semiconductor devices 1 can be collectively manufactured. For example, in this embodiment, the lead frame units 22 are formed in two lines in the first direction, and hence it is possible to subject two lines of lead frames units 22 to the processing at a time by using the tool section 34 movable in the first direction. Alternatively, in place of the above, two identical tool sections 34 are arranged in the first direction, and these tool sections 34 are simultaneously operated, whereby it is also possible to perform the processing for two lines at a time.

According to this embodiment, the effect stated below is obtained. That is, in order to restrain the vibration of the lead terminal 13 which has a thin and long shape extending in the first direction, and has one end in the longitudinal direction supported, the direction of the ultrasonic vibration is made the first direction along the length thereof, and hence it becomes possible to promote the friction between the connection conductor 16 and the lead terminal 13, and achieve firm bonding.

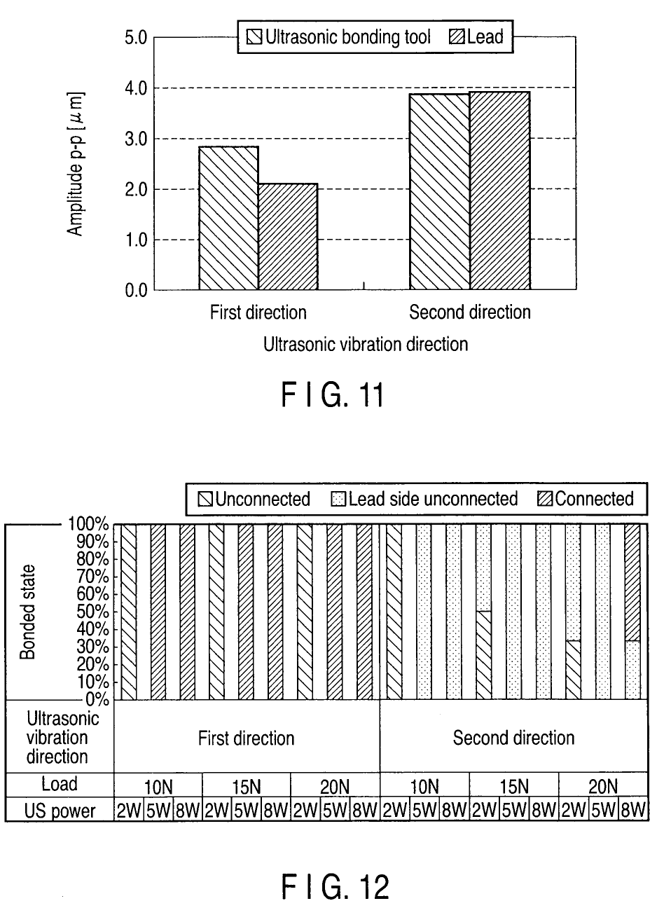

FIG. 11 shows results of measurement of the amplitude of the tool section, and the amplitude of the lead terminal at the time of ultrasonic bonding in each of a case where the ultrasonic vibration is applied in the first direction as shown in this embodiment, and a case where the ultrasonic vibration is applied in the second direction.

FIG. 12 shows results of checking the connection state of the connection conductor 16 and the lead terminal 13 obtained by changing the ultrasonic power and the load in each of a case where the ultrasonic vibration is applied in the first direction, and a case where the ultrasonic vibration is applied in the second direction.

In the graph of FIG. 12, the term “unconnected” implies a case where both the upper surface electrode 15 of the semiconductor chip 10 and the lead terminal 13 are not bonded to the connection conductor 16. Further, the term “lead side unconnected” implies a case where although the upper surface electrode 15 of the semiconductor chip 10 is bonded to the connection conductor 16, the lead terminal 13 is not bonded to the connection conductor. The term “connected” implies a case where both the upper surface electrode 15 of the semiconductor chip 10 and the lead terminal 13 are bonded to the connection conductor 16. The term “bonded state” implies the ratio of the number of cases where a plurality of semiconductor devices are subjected to ultrasonic bonding processing.

It can be seen from FIG. 11 that the amplitude of the tool section 34 is the same as the amplitude of the lead terminal 13 when the ultrasonic vibration is applied in the second direction. This implies that the metallic members are in motion together with each other as one body. Further, it can be seen from FIG. 12 that when the ultrasonic vibration is applied in the second direction, satisfactory bonding is not achieved.

On the other hand, it can be seen from FIG. 11 that when the ultrasonic vibration is applied in the first direction, the amplitude of the tool section 34 and the amplitude of the lead terminal 13 are different from each other, and the metallic members are in relative motion. Further, as shown in FIG. 12, it can be seen that satisfactory bonding is performed by an ultrasonic power equal to or higher than a predetermined level.

Particularly, when the materials of the metallic members to be bonded are different from each other, it is difficult to secure bonding strength. However, even in such a case, by the method of this embodiment, it becomes possible to achieve satisfactory bonding. Thus, it becomes possible to use an aluminum material, which is excellent in flexibility and formability, as the material for the connection conductor. As a result of this, it becomes possible to reduce the manufacturing cost.

Furthermore, in a case of a component small in size, or a thin and long lead, where a sufficient bonding area cannot be secured, it is difficult to secure the bonding strength, and hence the method of this embodiment is effective.

The lead terminal 13 is made to have a thin and long shape extending in the first direction, the connection conductor 16 is configured to extend in the second direction which is the transfer direction, and the filling direction of the resin 40 is made the first direction, whereby filling of the resin is performed satisfactorily.

Further, in this embodiment, the protrusions 37 and 38 of the first pressing section 35 and the second pressing section 36 bite into the connection conductor 16, and hence even when there are some dimension errors in the heights of the bonding parts, the bonding parts are simultaneously pressed in the same way, and the ultrasonic wave is securely propagated to each bonding part, whereby bonding is carried out with sufficient bonding strength.

It should be noted that the present invention is not limited to the embodiment described above as it is, and, in the implementation stage, the constituent elements can be modified and embodied within the scope not deviating from the gist of the invention. For example, the shapes and materials of the lead frame 20 and the upper surface electrode 15 are not limited to those in the above embodiment, and can be variously modified and used. In the embodiment described above, the case where the upper surface electrode 15 and the connection conductor 16 are constituted of an aluminum material, and the lead terminal 13 is constituted of copper has been described. However, the invention is not limited to this. For example, a case where the material for the upper surface electrode 15 is gold, and the material for the lead terminal 13 is aluminum, or a case where the material for the lead terminal 13 is copper, and the material for the connection conductor 16 is aluminum, are conceivable. Further, when the metallic members to be connected are of different materials or the same material, the same effect can be obtained.

In the embodiment described above, the case where the protrusions formed on the first and second pressing sections have a shape of a trapezoid of a quadrangular pyramid has been described. However, the present invention is not limited to this, and the protrusion may further be a protrusion having a shape of a trapezoid of a polyangular pyramid, protrusion having a shape of a trapezoid of a circular cone, or hemispherical protrusion.

Further, by appropriately combining a plurality of constituent elements disclosed in the embodiment described above with each other, various inventions can be obtained. For example, some constituent elements may be omitted from all the constituent elements shown in the embodiment. Furthermore, constituent elements of different embodiments may be appropriately combined with each other.

Additional advantages and modifications will readily occur to those skilled in the art. Therefore, the present invention in its broader aspects is not limited to the specific details, representative devices, and illustrated examples shown and described herein. Accordingly, various modifications may be made without departing from the spirit or scope of the general inventive concept as defined by the appended claims and their equivalents.

What is claimed is:

1. A method of manufacturing a semiconductor device comprising:
pressing a part of a connection conductor having a plate-like shape or a belt-like shape against a lead terminal which is formed on a lead frame, is formed into a long plate-like shape, and is supported only at one end in a longitudinal direction of the terminal, in such a manner that the part of the conductor is brought into contact with the lead terminal, and
applying ultrasonic vibration substantially in the longitudinal direction in a plane perpendicular to the pressing direction to the connection conductor in the state where the part of the connection conductor is pressed against the lead terminal.

2. The method of manufacturing a semiconductor device according to claim 1, wherein a material of the lead terminal, and a material of the connection conductor are different from each other.

3. The method of manufacturing a semiconductor device according to claim 1, wherein
in the pressing step, the other part of the connection conductor is pressed against an electrode of a semiconductor chip mounted on the lead frame in such a manner that the other part of the connection conductor is brought into contact with the electrode, and
in the ultrasonic vibration application step, ultrasonic vibration in the longitudinal direction is simultaneously applied to the part of the connection conductor and the other part thereof, whereby the lead terminal and the electrode are connected to each other through the connection conductor.

4. The method of manufacturing a semiconductor device according to claim 3, wherein
the lead frame includes a plurality of units each constituted of an island section on which the semiconductor chip is to be mounted, and the lead terminal, juxtaposed in one united body in a second direction perpendicular to a first direction parallel with the longitudinal direction,
the lead frame is transferred in the second direction, and the semiconductor chips mounted on the plurality of island sections and the plurality of lead terminals are subjected to the pressing, and ultrasonic vibration application in sequence from one end side in the second direction toward the other end side, whereby each of the plurality of semiconductor chips and the lead terminals on the lead frame are connected to each other through the connection conductor, and
a step of dividing a plurality of semiconductor devices formed to be juxtaposed on the lead frame in the second direction by the pressing step and the ultrasonic vibration application step in which each of the plurality of lead terminals, and each of the plurality of semiconductor devices are connected to each other by means of each of the plurality of connection conductors, into separate semiconductor devices is further provided.

5. An ultrasonic bonding apparatus comprising:
a stage on which a lead frame including a lead terminal having a thin and long shape, and semiconductor chips mounted thereon is to be placed; and
a tool section for pressing, in a state where a connection conductor having a plate-like shape or a belt-like shape is arranged astride an electrode formed on an upper surface of the semiconductor chip and the lead terminal, a part of the connection conductor against the lead terminal in such a manner that the part of the conductor is brought into contact with the lead terminal, and applying ultrasonic vibration substantially in the longitudinal direction of the lead terminal in a plane perpendicular to the pressing direction to the connection conductor in the state where the part of the connection conductor is pressed against the lead terminal.

6. The ultrasonic bonding apparatus according to claim 5, wherein a plurality of protrusions are formed on a pressing surface of the tool section, for pressing the connection conductor, and each of the protrusions is formed into a shape of a trapezoid of a polyangular pyramid, a trapezoid of a circular cone, or a hemisphere.
